(19) United States
(12) Patent Application Publication
(10) Pub. No.: US 2020/0010630 A1
(43) Pub. Date: Jan. 9, 2020

(54) POROUS FILM SEALING METHOD AND POROUS FILM SEALING MATERIAL

(71) Applicants: L'Air Liquide, Société Anonyme pour I'Etude et I'xpoloitation des Procédés Georges Claude, Paris (FR); Tokyo Electron Limited, Tokyo (JP)

(72) Inventors: Keiichiro URABE, Tsukuba (JP); Peng SHEN, Trsukuba (JP); Christian DUSSARRAT, Tokyo (JP); Taiki HATTORI, Tsukuba (JP); Shigeru TAHARA, Tokyo (JP)

(21) Appl. No.: 16/490,134

(22) PCT Filed: Mar. 1, 2018
(86) PCT No.: PCT/JP2018/007895

§ 371 Date: Aug. 30, 2019

(30) Foreign Application Priority Data
Mar. 3, 2017 (JP) 2017-040708

(51) Int. Cl. C08J 5/18

(52) U.S. Cl. CPC C08J 5/18; H01L 23/5329; C08J 2327/12

(57) ABSTRACT

A porous film sealing method and porous film sealing material are provided to seal an object to be sealed that has a porous film.

The porous film sealing method of the present invention is characterized by including a first step that supplies a first material to a treatment vessel in which is stored an object to be treated that has a porous film, and the first material includes a non-aromatic fluorocarbon having 6 or more carbon atoms.

### CROSS REFERENCE TO RELATED APPLICATIONS

This application is a 371 of International PCT Application PCT/JP2018/007895, filed Mar. 1, 2018, which claims priority to Japanese Patent Application No. 2017-040708, filed Mar. 3, 2017, the entire contents of which are incorporated herein by reference.

### TECHNICAL FIELD

The present invention relates to a porous film sealing method and a porous film sealing material.

### BACKGROUND ART

Porous films are used in wide-ranging fields such as water treatment, biotechnology, food products, cosmetics, medical care, diagnostics, semiconductors, and physicochemical analysis. However, porous films have poor mechanical strength and often sustain damage when processed.

In the semiconductor field, interlayer insulating film materials that have a low dielectric constant (referred to hereinafter as a “low-k films”) have been developed for the next generation of semiconductors. Low-k film is the generic designation for a film having a relative permittivity lower than 4.0. To reduce the relative permittivity of low-k film as much as possible, it is necessary to make a porous film that contains many holes. However, when holes are introduced, mechanical strength properties such as the modulus of elasticity and hardness decrease markedly in proportion to the quantity of holes, and because of this, problems readily arise such as easily sustaining damage from plasma etching and separation during processing. Thus, the problem to be solved in the semiconductor field has become how to provide both a low dielectric constant as well as process durability for low-k films.

To guard against excess damage while also being able to process the surface of a porous film, methods have been proposed to condense a compound in the porous film holes to protect the holes and reduced damage from etching (for example, see Patent Document 1). However, there is a narrow temperature range for carrying out the process of condensation of the compound, and because this temperature range is in a low temperature region, it is difficult to control the reaction, and large-scale equipment is needed for refrigeration.

In addition, methods to condense a compound in porous film holes as described in Patent Document 1 are carried out at extremely low temperatures. Because of this, liquid nitrogen is used as a refrigerant, and it is necessary to use processing equipment that can accommodate extremely low temperatures. Therefore, porous film etching methods have been proposed that do not require extremely low-temperature facilities (for example, Patent Document 2).

### PRIOR ART DOCUMENTS

### Patent Documents

Patent Document 1: Unexamined Patent Application Publication No. 2015-61073
Patent Document 2: Unexamined Patent Application Publication No. 2016-207768

### SUMMARY OF THE INVENTION

### Problems to be Solved by the Invention

The method disclosed in aforementioned Patent Document 2 uses an aromatic fluorocarbon such as C₆F₆ as the compound to be condensed within holes. However, these aromatic fluorocarbons have a high vapor pressure, which is to say that condensation occurs at a low temperature. Because of this, the condensation within porous film holes at comparatively high temperatures is insufficient. Hence, a material that condenses sufficiently in porous film holes at higher temperatures than heretofore and an improved sealing method for porous films are desired.

### Means for Solving the Problem

When etching a sealed porous film, while it is desirable for the interior of porous film holes to be sealed, the presence of sealing material in liquid form on the porous film surface has a negative effect on the etching process. Consequently, it is desirable for the temperature at which etching is performing to be set at a temperature condition below the temperature at which the sealing material condenses within the porous film holes by capillary condensation, and above the temperature at which said material liquefies under a prescribed pressure. In addition, a broader temperature range is preferred for etching to make control of etching conditions easier. Based on the above, the preferred sealing material for porous film is a compound in which there is a large difference between the liquefaction temperature of the material that seals the porous film and the temperature at which said material condenses by capillary condensation within the porous film holes under a prescribed pressure.

The inventors focused on the vapor pressure, boiling point, and the contact angle of said compound on porous film, and from the fact that the smaller the contact angle the larger the temperature difference between the liquefaction temperature and the temperature at which capillary condensation occurs, and knowledge of vapor pressure curves, contact angles, and the like, discovered the preferred compound for a sealing material for porous film and a porous film sealing method.

The present invention at least partially solves the aforementioned problem, and can be realized as the following embodiments or application examples.

### Application Example 1

One embodiment of the porous film sealing method of the present invention is a method for sealing holes within a porous film characterized by

comprising a first step that supplies a first material to a treatment vessel in which an object to be sealed that has porous film is stored, and

the first material comprises a non-aromatic fluorocarbon of 6 or more carbon atoms.

According to this application example, the first material comprising a non-aromatic fluorocarbon of 6 or more carbon atoms infiltrates the interior of porous film holes, and the porous film holes are sealed.

### Application Example 2

In the first step in the porous film sealing method of application example 1,

the first material is introduced into the treatment vessel in a gas state, and the first material is able to seal the holes within the porous film.

According to this application example, because the first material is introduced in a gas state, the first material gas disperses uniformly within the treatment vessel. The dispersed first material gas infiltrates the interior of the holes of the porous film by capillary condensation and is able to carry out uniform sealing.

### Application Example 3

In the first step in the porous film sealing method of application example 1 or application example 2,

the first material is introduced into the treatment vessel in a liquid state, and

the first material is able to seal the holes within the porous film.

According to this application example, the first material is not vaporized but is introduced in a liquid state. The supplied first material (liquid) infiltrates the interior of the holes of the porous film by capillary action and is able to carry out sealing.

### Application Example 4

The porous film sealing method of any one of application example 1 to application example 3 can further comprise a second step that generates a plasma from etching gas.

According to this application example, the first material infiltrates the holes of the porous film, and plasma etching can be performed in the sealed state. Consequently, etching can be carried out with little damage to the porous film.

### Application Example 5

In the porous film sealing method of application example 4,

the second step is carried out after the first step, and the first material can be used as an etching gas in the second step.

Because the porous film holes were sealed with the first material via the first step, the mechanical strength of the porous film improved. Thereby, etching can be carried out with little damage to the porous film. In addition, when etching is carried out in a second step, holes are opened in the exposed surface within the porous film by the etching. Under plasma conditions, when the applied first sealing material from the sections where holes were opened vaporizes and disperses, the first material can be used as an etching gas.

### Application Example 6

The porous film sealing method of any one of application example 1 to application example 5 can further comprise a third step that removes the first material from the holes in the porous film by increasing the temperature within the reaction vessel and/or decreasing the pressure within the reaction vessel.

According to this application example, the first material is vaporized by the third step and removed from the holes in the porous film, the porous film can be supplied to the next process. Note that after process 3 is complete, the overall process may be repeatedly performed again from first step.

### Application Example 7

In the porous film sealing method of any one of application example 1 to application example 6

the first material can have a ring structure, and the vapor pressure at a temperature of 25° C. can be from 0.05 Torr to 25 Torr.

According to this application example, the first material infiltrates the holes of the porous film and readily condenses at the temperature at which process 1 is performed. Consequently, sealing of the porous film becomes easier.

### Application Example 8

In the porous film sealing method of any one of application example 1 to application example 7,

the first material can have a straight chain or branched structure, and the vapor pressure at a temperature of 25° C. can be from 0.05 Torr to 40 Torr.

According to this application example, the first material infiltrates the holes of the porous film and readily condenses at the temperature at which process 1 is performed. When the first material is a straight-chain or branched structure, the steric structure of the molecule has a high degree of freedom, and is better suited than a cyclic structure to infiltration and condensation in the fine holes of a porous film.

### Application Example 9

In the porous film sealing method of any one of application example 1 to application example 8,

the first material can have a vapor pressure at a temperature range from −50° C. to −20° C. of from 0.0001 Torr to 0.1 Torr.

According to this application example, etching can be performed in a state in which the first material, which infiltrated and condensed in the holes of the porous film, persists within the holes.

### Application Example 10

In the porous film sealing method of any one of application example 1 to application example 9,

the first material can have a normal boiling point from 100 to 400° C. Here, normal boiling point refers to the temperature at which the vapor pressure of the first material is equal to atmospheric pressure (101,325 Pa).

### Application Example 11

In the porous film sealing method of any one of application example 1 to application example 10,

0% to 20% of the total number of atoms contained within a single molecule of the first material can be hydrogen atoms.

### Application Example 12

In the porous film sealing method of any one of application example 1 to application example 11,

0% to 5% of molecular weight of the first material can be the atomic weight of hydrogens.

According to this application example, the fraction of hydrogen contained within the first material is relatively small. Because of this, reduction of the porous film by the first material does not readily occur, and damage imparted to the device can be controlled.

### Application Example 13

In the porous film sealing method of any one of application example 1 to application example 12,

the first material can comprise one or more oxygen atoms and/or nitrogen atoms.

### Application Example 14

In the porous film sealing method of any one of application example 1 to application example 13,

the first material can have a contact angle on the porous film from greater than 0 degrees to 5 degrees or less.

According to this application example, the first material readily infiltrates the holes of the porous film by capillary action.

### Application Example 15

In the porous film sealing method of any one of application example 1 to application example 14,

the first material can be a compound represented by any of the general formulas of general formula (1) to general formula (4) below.

CR¹₃(CR²₂)ₙCR³₃ (1)

(where, in formula (1), the plurality of R¹ are each independently H, F, Cl, CF₃ or CHF₂, the plurality of R² are each independently H, F, Cl, CF₃ or CHF₂, the plurality of R³ are each independently H, F, Cl, CF₃ or CHF₂; n is an integer from 4 to 15)

CR⁴₃(O(CR⁵₂)ₘ)ₙOCR⁶₃ (2)

(where, in formula (2), the plurality of R⁴ are each independently H, F, Cl, CF₃ or CHF₂, the plurality of R⁵ are each independently H, F, Cl, CF₃ or CHF₂, the plurality of R⁶ are each independently H, F, Cl, CF₃ or CHF₂; n is an integer from 1 to 15, m is an integer from 1 to 4, and the number obtained by multiplying n times m is from 4 to 15)

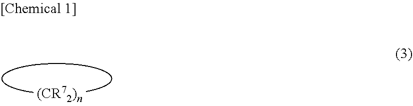

(where, in formula (3), the plurality of R⁷ are each independently H, F, Cl, CF₃ or CHF₂, and n is an integer from 6 to 17)

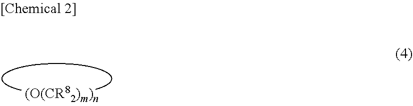

(where, in formula (4), the plurality of R⁸ are each independently H, F, Cl, CF₃ or CHF₂, n is an integer from 2 to 17, m is an integer from 1 to 4, and the number obtained by multiplying n times m is from 6 to 17)

### Application Example 16

In the porous film sealing method of any one of application example 1 to application example 15,

the first compound can be at least one compound selected from the group consisting of perfluorotributylamine, perfluorotripentylamine, perfluorotripropylamine, perfluorodecaline, perfluorotetradecahydrophenanthrene, perfluorooctane, perfluorononane, pefluorodecane, perfluoroundecane, perfluorotriglyme, perfluorotetraglyme, perfluoropentaglyme, perfluoro-1,4-dimethylcyclohexane, perfluoro-1,3,5-trimethylcyclohexane, perfluoro-1,2,4,5-tetramethylcyclohexane, perfluoro-15-crown-5-ether, and hexafluoropropylene oxide trimer.

### Application Example 17

In the porous film sealing method of any one of application example 1 to application example 16, the first material has a purity of 99.9 wt % to 100 wt % and can contain 0% to 0.1% water.

According to this application example, by using a non-aromatic fluorocarbon of 99.9 wt % to 100 wt % purity, containing 0% to 0.1% water, and having 6 or more carbon atoms, damage to porous films and to devices that contain porous films can be reduced. This reduction is attributable to an active species such as an oxygen radical or OH radical excited by plasma.

### Application Example 18

One embodiment of the porous film sealing material of the present invention is characterized by comprising a non-aromatic fluorocarbon have 6 or more carbon atoms.

According to this application example, a porous film sealing material comprising a non-aromatic fluorocarbon having 6 or more carbon atoms infiltrates the interior of porous film holes and seals the porous film holes.

### Application Example 19

The porous film sealing material of application example 18 can be used in the etching process.

According to this application example, because the porous film sealing material can infiltrate the interior of porous film holes by capillary condensation and seal the holes, and damage to the porous film in the etching process can be reduced.

### Application Example 20

The porous film sealing material of application example 18 or application example 19 can have a ring structure and have a vapor pressure at a temperature of 25° C. of 0.05 Torr to 25 Torr.

According to this application example, the porous film sealing material infiltrates the holes of the porous film and readily condenses at the temperature at which the hole of the porous film is sealed. Consequently, sealing porous film becomes easier.

### Application Example 21

The porous film sealing material of application example 18 or application example 19 can have a straight-chain or branched structure and have a vapor pressure at a temperature of 25° C. of 0.05 Torr to 40 Torr.

According to this application example, the porous film sealing material infiltrates the holes of the porous film and readily condenses at the temperature at which the film of the porous film is sealed. When the porous film sealing material has a straight-chain or branched structure, the steric structure of the molecule has a high degree of freedom, and is more suitable than a cyclic structure for infiltration and condensation in the fine holes of a porous film.

### Application Example 22

In the porous film sealing material of any one of application example 18 to application example 21, the porous film sealing material can have a vapor pressure at a temperature range from −50° C. to −20° C. of 0.0001 Torr to 0.1 Torr.

According to this application example, etching can be performed in a condition in which the porous film sealing material has sealed the porous film.

### Application Example 23

The porous film sealing material of any one of application example 18 to application example 22 can have a normal boiling point of 100 to 400° C.

### Application Example 24

In the porous film sealing material of any one of application example 18 to application example 23, 0% to 20% of the total number of atoms contained within a single molecule are hydrogen atoms.

According to this application example, because the fraction of hydrogen atoms contained in the porous film sealing material is small, the reduction of the porous film by the porous film sealing material does not readily occur, and damage imparted to the device can be controlled.

### Application Example 25

In the porous film sealing material of any one of application example 18 to application example 23, 0% to 5% of the molecular weight is the atomic weight of hydrogen atoms.

### Application Example 26

The porous film sealing material of any one of application example 18 to application example 25 can comprise one or more oxygen atoms and/or nitrogen atoms.

### Application Example 27

The porous film sealing material of any one of application example 18 to application example 26 can have a contact angle on the porous film of greater than 0 degrees and less than 5 degrees.

According to this application example, the porous film contact material readily infiltrates the holes of the porous film by capillary action.

### Application Example 28

The porous film sealing material of any one of application example 18 to application example 27 can be a compound expressed by any of the general formulas below from general formula (1) to general formula (4).

CR¹₃(CR²₂)ₙCR³₃ (1)

(where, in formula (1), the plurality of R¹ are each independently H, F, Cl, CF₃ or CHF₂, the plurality of R² are each independently H, F, Cl, CF₃ or CHF₂, the plurality of R³ are each independently H, F, Cl, CF₃ or CHF₂; n is an integer from 4 to 15)

CR⁴₃(O(CR⁵₂)ₘ)ₙOCR⁶₃ (2)

(where, in formula (2), the plurality of R⁴ are each independently H, F, Cl, CF₃ or CHF₂, the plurality of R⁵ are each independently H, F, Cl, CF₃ or CHF₂, the plurality of R⁶ are each independently H, F, Cl, CF₃ or CHF₂; n is an integer from 1 to 15, m is an integer from 1 to 4, and the number obtained by multiplying n times m is from 4 to 15)

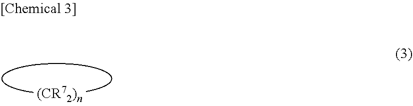

(where, in formula (3), the plurality of R⁷ are each independently H, F, Cl, CF₃ or CHF₂, and n is an integer from 6 to 17)

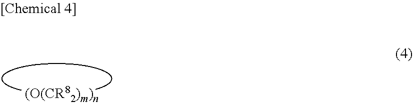

(where, in formula (4), the plurality of R⁸ are each independently H, F, Cl, CF₃ or CHF₂, n is an integer from 2 to 17, m is an integer from 1 to 4, and the number obtained by multiplying n times m is from 6 to 17)

### Application Example 29

The porous film sealing material of any one of application example 18 to application example 27 can be at least one compound selected from the group consisting of perfluorotributylamine, perfluorotripentylamine, perfluorotripropylamine, perfluorodecaline, perfluorotetradecahydrophenanthrene, perfluorooctane, perfluorononane, pefluorodecane, perfluoroundecane, perfluorotriglyme, perfluorotetraglyme, perfluoropentaglyme, perfluoro-1,4-dimethylcyclohexane, perfluoro-1,3,5-trimethylcyclohexane, perfluoro-1,2,4,5-tetramethylcyclohexane, perfluoro-15-crown-5-ether, and hexafluoropropylene oxide trimer.

### Application Example 30

The porous film sealing material of any one of application example 18 to application example 29 can have a purity of 99.9 wt % to 100 wt % and can contain 0% to 0.1% water.

According to this application example, by using a porous film sealing material of 99.9 wt % to 100 wt % purity containing 0% to 0.1% water, damage to porous films and to devices that contain porous films can be reduced. This reduction is attributable to an active species such as an oxygen radical or OH radical excited by plasma.

### Effect of the Invention

According to the porous film sealing method of the present invention, a first material, which is a non-aromatic fluorocarbon having 6 or more carbon atoms, is supplied to a treatment vessel that stores the porous-film-containing object to be sealed, and thereby, the first material infiltrates the interior of the porous film holes and seals the holes. By sealing the holes with the first material, etching can be carried out with little damage to the porous film.

### BRIEF DESCRIPTION OF THE DRAWINGS

FIG. 1 is a conceptual illustrative diagram of a porous film sealing method pertaining to this embodiment.

FIG. 2 is a block diagram of a porous film sealing equipment preferably used in this embodiment.

FIG. 3 is a diagram presenting the flow of the porous film sealing method pertaining to this embodiment.

FIG. 4 presents vapor pressure curves of various materials used in this embodiment.

FIG. 5 presents vapor pressure curves of various materials used in this embodiment.

FIG. 6 is a block diagram of a porous film sealing equipment preferably used in this embodiment.

### MODE FOR CARRYING OUT THE INVENTION

The preferred embodiments pertaining to the present invention are described in detail below. Note that the present invention is not limited by the embodiments described below, and it should be understood that various modifications may be included that were made to an extent that does not deviate from the substance of the present invention.

### 1. POROUS FILM SEALING METHOD

The porous film sealing method of this embodiment is characterized by comprising a first step that supplies a first material to a treatment vessel that stores an object to be sealed that has a porous film, and the first material is a non-aromatic fluorocarbon having 6 or more carbon atoms. The porous film sealing method of the this embodiment may further comprise as necessary a second step that generates a plasma from etching gas, and a third step to remove the first material from the holes within the porous film. After the third step is complete, the overall process may be repeatedly performed again from the first step.

The porous film sealing method of this embodiment can be used for sealing of the holes of porous-film-containing objects (for example filter materials, porous films, Low-k films, etc.), and can be used suitably in fields such as water treatment, semiconductors, and food products.

Objects to be sealed are not particularly limited, and porous film forms that are supported on a substrate are completely acceptable, and free-standing porous films are acceptable. In addition, porous films in which each hole within the film exists separately are acceptable, and porous films in which adjacent holes within a film are partially or completely interconnected are acceptable. The size of the holes in a porous film is not particularly restricted, however, the diameter is usually 0.1 to 5000 nm. When the porous film is a Low-k film, the hole size diameter is preferably 0.1 to 100 nm.

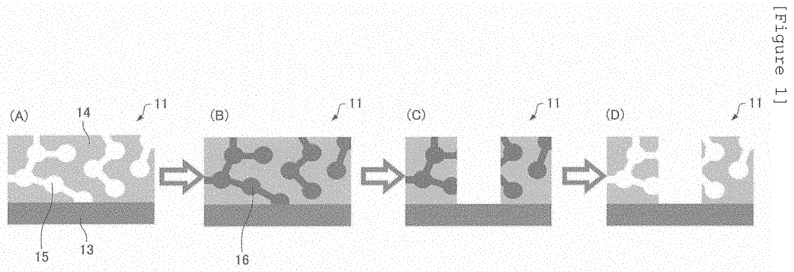

The general idea of the porous film sealing method of this embodiment is described with reference to the drawings. FIG. 1 presents a conceptual illustrative diagram of the porous film sealing method pertaining to this embodiment. FIG. 1(A) shows object to be sealed 11 prior to the first step. As shown in FIG. 1(A), object to be sealed 11 is, for example, possessed of porous film 14, which has a plurality of holes 15, above substrate 13.

FIG. 1(B) shows object to be sealed 11 after completion of the first step. In the first step, the first material 16 functions as a porous film sealing material by infiltrating and condensing in holes 15. By thus sealing holes 15 of porous film 14, mechanical strength properties of porous film 14 such as modulus of elasticity and hardness improve.

FIG. 1(C) shows object to be sealed 11 after the completion of the second step, that is, etched after the completion of the first step. Because the first material infiltrated and condensed in holes 15 of porous film 14 in the first step, the damage sustained by porous film 14 in the second step which carries out plasma etching can be reduced. More specifically, the breakdown phenomenon of the three-dimensional shape of holes 15 of porous film 14 can be controlled by the active species generated by the plasma. In addition, when porous film 14 is etched in the second step, the holes sealed by the first material are opened in porous film surfaces that are newly emergent as a result of etching. At least part of the first material transpires from the opened-hole areas, and the transpired first material may function as an etching gas.

FIG. 1(D) shows object to be sealed 11 after completion of the third step. The first material is removed by the below-described third step after completion of the second step.

Each stage of work for the porous film sealing method of this embodiment is described for each step.

### 1.1. The First Step

The first step is a process that supplies the first material to the treatment vessel that stores the porous-film-containing object to be sealed. In the first step, porous film holes can be sealed by the first material. Any method known to a person skilled in the art for introducing the material can be used to supply the first material to the treatment vessel.

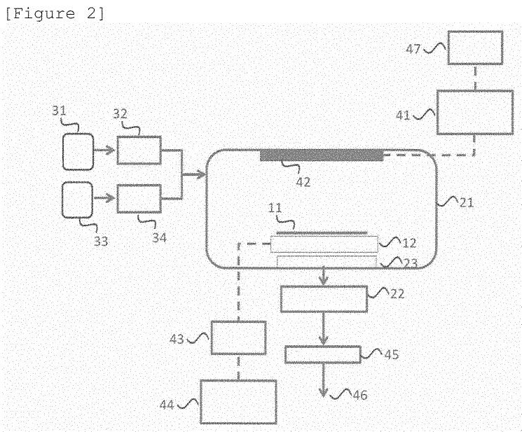

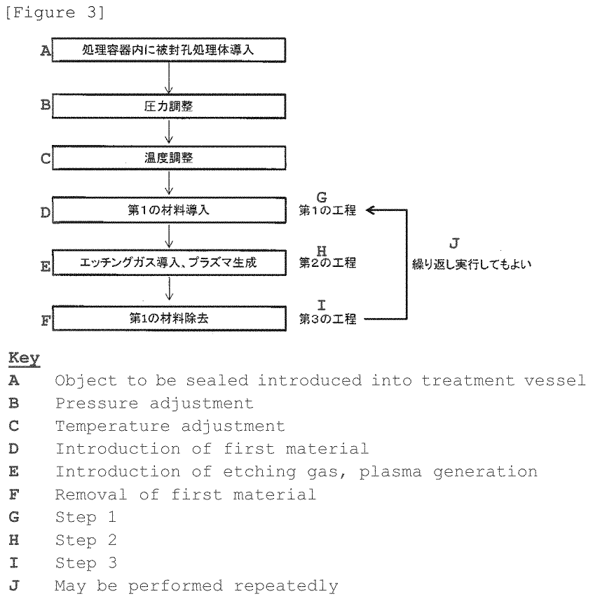

Below, the porous film sealing method performed in the first step is described with reference to the drawings. FIG. 2 is a block diagram of equipment preferably used in this embodiment. FIG. 3 is a diagram presenting the flow of the porous film sealing method of this embodiment.

First, porous-film-containing object to be sealed 11 is stored in treatment vessel 21. About 1 to 200 objects to be sealed can be stored in treatment vessel 21 for sealing treatment. Porous-film-containing objects to be sealed 11 differ depending on the application. Specific examples of objects to be sealed 11 may include but are not limited to porous silica, porous carbon, and porous carbon ceramic composite, or low-k film or fluorocarbon porous film containing combinations thereof, or other porous film containing a combination of all these materials.

At this time, the pressure within treatment vessel 21 is set to a specified pressure by pressure regulating mechanism 22, and the temperature within treatment vessel 21 is set to a specified temperature by temperature control mechanism 23. A back pressure valve or pressure regulating valve can be used for pressure regulating mechanism 22, but the mechanism is not restricted thereto. A temperature control mechanism that combines cooling by means of a refrigerant (for example, liquid nitrogen, isopropyl alcohol, etc.) and heating by a heater can be used for temperature control mechanism 23, but the mechanism is not restricted thereto. The temperature and pressure at which the first step and the second step are performed can each be different values.

The temperature within treatment vessel 21 can be set to a temperature in the range of −70° C. to 25° C. by temperature control mechanism 23. The lower temperature limit in reaction vessel 21 is preferably −70° C., more preferably −30° C., and still more preferably −20° C. The upper temperature limit in reaction vessel 21 is preferably 25° C. and more preferably 20° C.

The lower pressure limit in reaction vessel 21 is preferably 0.01 mTorr, more preferably 0.05 mTorr, and still more preferably 0.1 mTorr. The upper pressure limit in reaction vessel 21 is preferably 1000 mTorr, more preferably 500 mTorr, and still more preferably 100 mTorr.

Treatment vessel 21 can be made of stainless steel, for example, but is not limited thereto.

Next, the first material which comprises a non-aromatic fluorocarbon having 6 or more carbons is introduced into treatment vessel 21. At this time, the first material can be introduced into treatment vessel 21 in a gas state or a liquid state. In the case where the first material is introduced in a gas state, it is preferable to use a method in which vapor of the first material is introduced from first material vessel 31 (including the method of introducing sublimated first material), a direct injection method in which liquid drops of the first material are dropped onto a heater, and the generated vapor is introduced, or a method in which a carrier gas is introduced to the first material vessel 31, and through bubbling, first material vapor is entrained and introduced, but the method of introduction is not limited to these. In the case where the first material is introduced in a liquid state, it is preferable to use the method of dropping liquid drops into treatment vessel 21 and vaporizing the liquid, but the method is not limited to this, and liquid drops may be dropped directly onto the porous film. Upon introducing the first material into to treatment vessel 21 in a gas state or a liquid state, the flow rate of the first material can be controlled by flow regulating mechanism 32. Depending on the characteristics, properties, and the like of the first material, a mass flow controller, a variable leak valve, or a liquid flow meter can be used for flow regulating mechanism 32, but the mechanism is not limited thereto.

In treatment vessel 21, just sealing treatment of porous film can be performed, however, the etching of the second step and/or the removal of the first material of the third step can also be performed. The second step and third step are described in detail below.

The flow rate of the first material introduced into to treatment vessel 21 is set, for example, to a gas flow rate or liquid flow rate in the range of 0.1 to 2000 SCCM by flow regulating system 32. The aforementioned flow rate can be changed depending on the volume of treatment vessel 21, the number of objects to be sealed, the properties of the first material, and the like.

The time over which the first material is introduced into treatment vessel 21 flow rate can be changed depending on the volume of treatment vessel 21, the number of objects to be sealed, the properties of the first material, and the like. For example, the time can range from 5 seconds to 60 minutes.

Thus, the holes of the object to be sealed are sealed by the first material in treatment vessel 21. When the first material in treatment vessel 21 is in the gaseous state, it infiltrates holes by capillary condensation. In addition, when the first material in treatment vessel 21 is in the liquid state and liquid drops are supplied directly to the porous film, it infiltrates holes by capillary action.

### <The First Step>

The first material is not particularly limited provided it is a material containing a non-aromatic fluorocarbon having 6 or more carbon atoms. Non-aromatic fluorocarbon has carbon-carbon bonds that have a high degree of rotational and extensional freedom and it has a steric structure that is flexible compared to aromatic fluorocarbon, and therefore, readily infiltrates porous film.

When the first material has a cyclic structure, the lower vapor pressure limit at 25° C. is preferably 0.05 Torr, and more preferably 0.5 Torr. The upper limit is preferably 25 Torr, and more preferably 20 Torr.

When the first material has a straight-chain or branched structure, the lower vapor pressure limit at 25° C. is preferably 0.05 Torr, and more preferably 0.5 Torr. The upper limit is preferably 40 Torr, and more preferably 25 Torr.

If the vapor pressure of the first material is within the limits described above, the first material readily infiltrates into and condenses in the porous film holes at the temperature and pressure conditions implemented in the first step. When the material is a straight-chain or branched structure, there is a still higher degree of rotational and extensional freedom in the bonds between the atoms than a compound having a cyclic structure. Because of this, the suitable vapor pressure range can be widened for the first material.

The lower vapor pressure limit of the first material at a temperature from −50° C. to −20° C. is preferably 0.0001 Torr, and more preferably 0.001 Torr. The upper limit is preferably 0.1 Torr, and more preferably 0.05 Torr.

If the vapor pressure of the first material at a temperature of −50° C. to −20° C. is within the limits described above, sealing readily occurs, and these conditions are also preferable because the etching of the second step can be performed at about the same temperature and pressure conditions as the first step that seals the holes.

The lower limit for the normal boiling point of the first material is preferably 100° C., and more preferably 110° C. The upper limit is preferably 400° C., and more preferably 250° C.

It is preferable that 0% to 20% of the total number of atoms contained in a single molecule of the aforementioned first material are hydrogen atoms.

In addition, it is preferable that 0% to 5% of the molecular weight of the aforementioned first material is the atomic weight of the hydrogen atoms.

When the fraction of hydrogen atoms contained with the first material is small, reduction of the porous film by the first material does not readily occur. Consequently, damage to porous film or a device containing porous film can be held down.

The first material can comprise one or more oxygen atoms and/or nitrogen atoms. First materials that contain oxygen atoms include straight-chain, branched, or cyclic ethers, ketones, anhydrides, alcohols, and mixtures thereof, but are not limited thereto. First materials that contain nitrogen atoms include straight-chain, branched, or cyclic amines and mixtures thereof, but are not limited thereto.

The first material has a contact angle on the porous film of the aforementioned object to be sealed of preferably greater than 0 degrees and less than 5 degrees. When the contact angle is greater than 0 degrees and less than 5 degrees, the first material infiltrates porous film holes through capillary action and condenses particularly readily.

Note that contact angle of the first material on porous film of the present invention refers to the static contact angle determined by the liquid drop method presented below.

(1) Porous film is left standing in air at a temperature of 25° C.
(2) Using a microsyringe, 10 μL of the first material is dropped onto porous film in a horizontal state.
(3) In a stationary condition, the liquid drop of first material that was applied as a drop is photographed directly from the side using a digital camera.
(4) From the photographed image, the angle formed by the porous film and a line tangent to the surface of the liquid drop (first material) at the point of contact of the liquid drop on the porous film is calculated as the contact angle.

The first material is more preferably a compound represented by any of the general formulas of general formulas (1) to (4) or a mixture thereof.

CR¹₃(CR²₂)ₙCR³₃ (1)

(where, in formula (1), the plurality of R¹ are each independently H, F, Cl, CF₃ or CHF₂, the plurality of R² are each independently H, F, Cl, CF₃ or CHF₂, the plurality of R³ are each independently H, F, Cl, CF₃ or CHF₂; and n is an integer from 4 to 15)

CR⁴₃(O(CR⁵₂)ₘ)ₙOCR⁶₃ (2)

(where, in formula (2), the plurality of R⁴ are each independently H, F, Cl, CF₃ or CHF₂, the plurality of R⁵ are each independently H, F, Cl, CF₃ or CHF₂, the plurality of R⁶ are each independently H, F, Cl, CF₃ or CHF₂; n is an integer from 1 to 15, m is an integer from 1 to 4, and the number obtained by multiplying n times m is from 4 to 15)

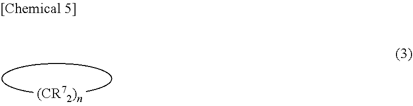

(where, in formula (3), the plurality of R⁷ are each independently H, F, Cl, CF₃ or CHF₂, and n is an integer from 6 to 17)

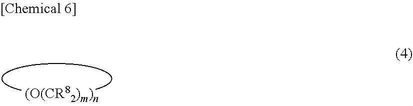

(where, in formula (4), the plurality of R⁸ are each independently H, F, Cl, CF₃ or CHF₂, n is an integer from 2 to 17, m is an integer from 1 to 4, and the number obtained by multiplying n times m is from 6 to 17)

In general formula (1), R¹, R² or R³ include H, F, Cl, CF₃, and CHF₂, however, CF₃ or F are each independently more preferred. n is an integer from 4 to 15, preferably an integer from 6 to 12, and more preferably an integer from 7 to 10.

In general formula (2), R⁴, R⁵, or R⁶ include H, F, Cl, CF₃, and CHF₂, however, CF₃ or F are each independently more preferred. n is an integer from 1 to 15, preferably an integer from 2 to 10, and more preferably an integer from 3 to 6. m is an integer from 1 to 4, preferably an integer from 1 to 3, and more preferably an integer from 1 to 2.

In general formula (3), R⁷ includes H, F, Cl, CF₃, and CHF₂, however, CF₃ or F are each independently more preferred. n is an integer from 6 to 17, preferably an integer from 7 to 15, and more preferably an integer from 8 to 12.

In general formula (4), R⁸ includes H, F, Cl, CF₃, and CHF₂, however, CF₃ or F are each independently more preferred. n is an integer from 2 to 17, preferably an integer from 3 to 15, and more preferably an integer from 4 to 12. m is an integer from 1 to 4, and preferably an integer from 2 to 3.

The compound represented by any general formula of aforementioned general formula (1) to general formula (4) may be a perfluoro compound and may be a hydrofluoro compound having 1 or more hydrogen atoms.

Specific examples of the first material include perfluorotributylamine, perfluorotripentylamine, perfluorotripropylamine, perfluorodecaline, perfluorotetradecahydrophenanthrene, perfluorooctane, perfluorononane, pefluorodecane, perfluoroundecane, perfluorotriglyme, perfluorotetraglyme, perfluoropentaglyme, perfluoro-1,4-dimethylcyclohexane, perfluoro-1,3,5-trimethylcyclohexane, perfluoro-1,2,4,5-tetramethylcyclohexane, perfluoro-15-crown-5-ether, and hexafluoropropylene oxide trimer. These can be used singly or as a mixture of two or more compounds.

The first material preferably has a purity of 99.9 wt % to 100 wt % and contains 0% to 0.1% water.

By using a first material of 99.9 wt % to 100 wt % purity containing 0% to 0.1% water, damage to porous films and to devices that contain porous films can be reduced. This reduction is attributable to an active species such as an oxygen radical or OH radical excited by plasma.

### 1.2. The Second Step

The porous film sealing method according to this embodiment can further comprise a second step that generates a plasma from etching gas. The second step is performed preferably in treatment vessel 21 in which the first step is performed after the completion of the first step, however, it is also acceptable to transfer the object to be sealed to a separate treatment vessel after the conclusion of the first step and perform the second step.

The porous film is etched when plasma from the etching gas is generated in the second step. Because the first material infiltrates and condenses in the holes of the porous film by the sealing treatment performed in the first step, the mechanical strength of the porous film improves, and damage to the porous film from plasma etching in the second step can be reduced.

The etching gas used can be any gas known to a person skilled in the art, and for example, can include at least one gas selected from the group consisting of SF₆, SiF₄, NF₃, CF₄, CHF₃, CH₂F₂, C₄F₈, C₄F₆, O₂, CO₂, CO, N₂, He, Ar, Ne, Kr, and Xe. The aforementioned first material can also be included.

In the second step, the pressure within treatment vessel 21 is set to a specified pressure by pressure regulating mechanism 22, and the temperature within treatment vessel 21 is set to a specified temperature by temperature control mechanism 23. A back pressure valve or pressure regulating valve can be used for pressure regulating mechanism 22, but the mechanism is not restricted thereto. A temperature control mechanism that combines cooling by means of liquid nitrogen and heating by a heater can be used for temperature control mechanism 23, but the mechanism is not restricted thereto. The temperature and pressure at which the first step and the second step are performed can each be different values.

In the second step, the temperature within treatment vessel 21 can be set to a temperature in the range of −70° C. to 25° C. by temperature control mechanism 23. The lower temperature limit in reaction vessel 21 is preferably −70° C., more preferably −30° C., and still more preferably −20° C. The upper temperature limit in reaction vessel 21 is preferably 25° C. and more preferably 20° C.

In the second step, the lower pressure limit in reaction vessel 21 is preferably 0.01 mTorr, more preferably 0.05 mTorr, and still more preferably 0.1 mTorr. The upper pressure limit in reaction vessel 21 is preferably 1000 mTorr, more preferably 500 mTorr, and still more preferably 100 mTorr.

The flow rate for the etching gas introduced into treatment vessel 21 can be changed depending on the volume of treatment vessel 21, the number of objects to be sealed, the properties of the first material, and the like. The flow rate of the aforementioned etching gas is regulated by flow regulating system 34 and, for example, can be set to a gas flow rate in the range of 1 SCCM to 3000 SCCM.

### 1.3. The Third Step

The porous film sealing method of this embodiment can further comprise a third step that removes the first material from the holes in the porous film by increasing the temperature within reaction vessel 21 and/or decreasing the pressure within reaction vessel 21. Either approach of increasing the temperature or decreasing the pressure within treatment vessel 21 can be selected, or both approaches can be implemented. The third step can be performed after the completion of the second step in treatment vessel 21 in which the first step and/or the second step are performed.

In process 3, when the temperature of treatment vessel 21 is raised, the temperature within treatment vessel 21 is set to a specified temperature by temperature control mechanism 23. In the third step, when the pressure of treatment vessel 21 is reduced, the pressure within treatment vessel 21 is set to a specified pressure by pressure regulating mechanism 22. A back pressure valve or pressure regulating valve can be used for pressure regulating mechanism 22, but the mechanism is not restricted thereto.

In the third step, the temperature within treatment vessel 21 can be set to a temperature range that is no lower than the temperature at which the first step was performed and is no higher than 50° C. The lower temperature limit in reaction vessel 21 is preferably the temperature at which the first step was performed, more preferably the temperature at which the first step was performed plus 10° C., and still more preferably the temperature at which the first step was performed plus 50° C. The upper temperature limit in reaction vessel 21 is preferably 50° C. and more preferably 20° C.

In the third step, the lower pressure limit in reaction vessel 21 is preferably 0.0001 mTorr, more preferably 0.005 mTorr, and still more preferably 0.1 mTorr. The upper pressure limit in reaction vessel 21 is preferably less than 1000 mTorr, more preferably 500 mTorr, and still more preferably 100 mTorr.

After the completion of the third step, the interior of treatment vessel 21 is purged, the temperature is returned to a predetermined temperature (for example, 25° C.), and the object to be sealed 11 can be removed from treatment vessel 21. After the third step is complete, the overall process may be repeatedly performed again from the first step.

### 1.4. Effect

According to the porous film sealing method of this embodiment, the first material is supplied to a treatment vessel that receives the porous-film-containing object to be sealed, and the first material infiltrates and condenses in the interior of the porous film holes. Thus, the holes of the porous film are sealed. Damage to the porous film from etching can be controlled by performing plasma etching while the porous film holes are kept sealed with the first material. Hence, the sealing in the first step is suitable for etching of porous film that is easily damaged by plasma. In this case, because etching is carried out in a state in which the first material has sealed the holes of the porous film, etching can be carried out while maintaining the three-dimensional shape of the porous film holes.

In the porous film sealing method of this embodiment, a non-aromatic fluorocarbon having 6 or more carbon atoms is applicable as a sealing material. In the method for sealing porous film and carrying out etching, there is a tendency for the porous film to sustain damage in the etching process and for the three-dimensional shape of the porous film holes to be disrupted because the sealing of the porous film is insufficient. In this case, the original dielectric properties of the porous film are lost, which causes damage to the device. However, according to the porous film sealing method of this embodiment, the first material, which is a porous film sealing material, readily infiltrates and condenses in the holes of the porous film. This is because non-aromatic fluorocarbon having 6 or more carbon atoms contains bonds within the molecule that are suitable for sealing which have a high degree of rotational and extensional freedom and can readily infiltrate the holes of porous film. Damage to porous film can be decreased in the etching process (second step), which immediately follows the first step that performs sealing.

### 2. EXAMPLES

The present invention is described specifically below based on examples, however, the invention should not be construed as being limited by these examples.

### 2.1 Vapor Pressure Measurement of Each Material

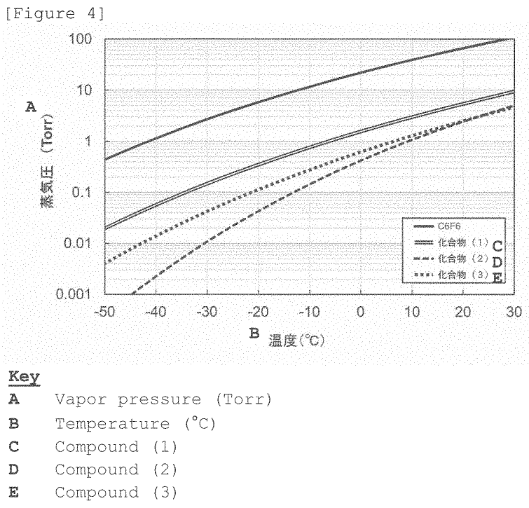

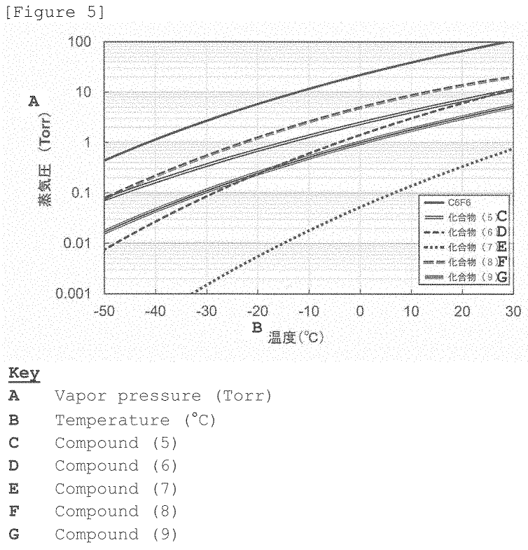

FIG. 4 and FIG. 5 present the results (vapor pressure curves) of vapor pressures measured at various temperatures for each of the materials shown in Table 1 below. Vapor pressure measurements were performed by placing the material to be measured into a stainless steel vessel, cooling the entire vessel, and then making measurements of the pressure within the vessel while gradually raising the temperature. Table 1 below also presents the vapor pressure at 25° C. of each material read from FIG. 4 and FIG. 5.

### <Measurement Conditions>

Device name: Pressure gauge 722B, manufactured by MKS Co.

Cryostat: PSL-2500B, manufactured by EYELA Co.

Measurement temperature: −50° C. to 30° C.

As shown in Table 1, the vapor pressure of aromatic fluorocarbon C₆F₆ at 25° C. was over 25 Torr (measured value 58 Torr). Similarly, the vapor pressure of aromatic fluorocarbon C₇F₈ at 25° C. was over 25 Torr (measured value 29 Torr). By contrast, in the case non-aromatic fluorocarbons having a cyclic structure of 6 or more carbon atoms (Compound Numbers 1, 2, 3, and 4 in Table 1), the vapor pressure at 25° C. was in the range from 0.05 Torr to 25 Torr. In the case of non-aromatic fluorocarbons having a straight-chain or branched structure of 6 or more carbon atoms (Compound Numbers 5, 6, 7, 8, and 9 in Table 1), the vapor pressure at 25° C. was in the range from 0.05 Torr to 40 Torr.

As shown in FIG. 4, the vapor pressure of aromatic fluorocarbon C₆F₆ in the range from −50° C. to −20° C. was above 0.1 mTorr (measured value 0.4 Torr or greater). By contrast, the vapor pressures of non-aromatic fluorocarbons having a cyclic structure of 6 or more carbon atoms (Compound Numbers 1, 2, and 3) in the range from −50° C. to −20° C. were in the range from 0.0001 Torr to 0.1 Torr.

In addition, as shown in FIG. 5, the vapor pressures of non-aromatic fluorocarbons having a straight-chain or branched structure of 6 or more carbon atoms (Compound Numbers 5, 6, 7, 8, and 9) in the range from −50° C. to −20° C. were in the range from 0.0001 Torr to 0.1 Torr.

### 2.2 Normal Boiling Point Measurement of Each Material

Table 2 below presents the results of measurements of normal boiling point for each of the materials shown in Table 2 below. Measurements of normal boiling point used the same device as the aforementioned vapor pressure determination method and were carried out by observing the temperature when the vapor pressure of the compound being measured reached 101,325 Pa.

As shown in Table 2 above, the normal boiling point of aromatic fluorocarbon C₆F₆ was below 100° C. (measured value 81° C.). By contrast, the normal boiling points of non-aromatic fluorocarbons having 6 or more carbon atoms (Compound Numbers 1 to 14) were from 100° C. to 400° C.

### 2.3 Contact Angle Measurement of Each Material

Table 3 below presents the results of measurements of contact angle for each of the materials shown in Table 3 below. Note that contact angle measurements were performed according to the following procedure.

(1) Porous film is left standing in air at a temperature of 25° C.
(2) Using a microsyringe, 10 μL of the material shown in Table 3 below is dropped onto the porous film in a horizontal state.
(3) In a stationary condition, the liquid drop of the material that is applied as a drop was photographed directly from the side using a digital camera.
(4) From the photographed image, the angle formed by the porous film and a line tangent to the surface of the liquid drop (first material) at the point of contact of the liquid drop on the porous film is calculated as the contact angle.
(5) Black Diamond™ 3 film (k value ˜2.5) purchased from Advantive Technologies was used for the porous film. Black Diamond™ 3 film is a nano porous film formed by preparing an organic silicate glass “backbone” from PECVD growth and a thermally unstable organic layer, then removing the unstable layer by ultraviolet curing (porosity is formed at this point), and reconstituting and reconstructing the silicon oxide matrix.

As shown in Table 3, the contact angle of aromatic fluorocarbon C₆F₆ was 9 degrees and C₇C₈ was 10 degrees. On the other hand, among the first materials on porous film, the contact angles of material numbers 3, 5, 7, 8, and 9 were less than 5 degrees.

### 2.4. The First Step

Any one of the compounds shown in Table 4 was supplied to the treatment vessel that stores the porous-film-containing object to be sealed, and sealing was performed under the conditions described below. Table 4 below presents the results of measurements of the refractive index of the porous film before and after sealing. The refractive index of porous film when the first material infiltrated and condensed in the holes of the porous film increased more than the refractive index of porous film when the first material did not infiltrate and condense. When the refractive index after sealing increased by 5% or more compared to the refractive index before sealing, the sealing condition was judged to be good and was marked as “o”. When the refractive index after sealing increased by 1% or more but less than 5%, the sealing condition was judged to be acceptable was marked as “a”. When the refractive index after sealing increased by less than 1%, the sealing condition was judged to be insufficient was marked as “x”.

### <Sealing Conditions>

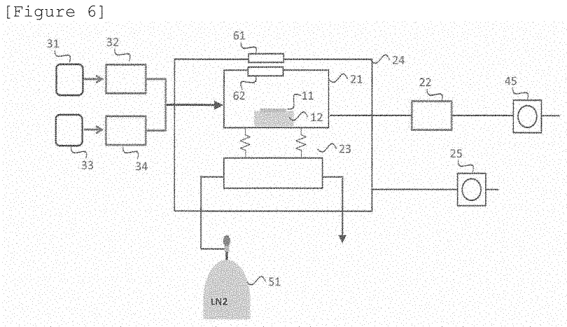

Equipment used: FIG. 6 shows the porous film sealing equipment used. The porous film sealing equipment shown in FIG. 6 is furnished with vacuum housing pump 25 which is connected to vacuum housing 24 equipped with glass window 61, internal to which is treatment vessel 21 equipped with glass window 62, and temperature control mechanism 23. Temperature control mechanism 23 is connected to refrigerant container 51 and can arbitrarily control the temperature within treatment vessel 21. In addition, treatment vessel 21 is connected to first material vessel 31 via first material flow regulating mechanism 32 and is connected to etching gas vessel 33 via etching gas flow regulating mechanism 34 so that the first material and etching gas can be introduced into treatment vessel 21. Treatment vessel 21 is connected to pressure regulating mechanism 22 and treatment vessel vacuum pump 45. The pressure within the treatment vessel can be arbitrarily controlled to regulate the flow rate of first material and etching gas.

Treatment vessel: Stainless steel vessel, 0.05 L capacity

Sealing temperature: −40° C.

Object to be sealed: Black Diamond™ 3 film purchased from Advantive Technologies

Pressure within treatment vessel: 0.03 Torr

Porous film sealing material (first material): Material Numbers 1, 2, 3, 4, 5, 6, 7, 8, 9, 10, 11, 12, 13, 14, C₆F₆, C₇F₈

Sealing time: 3 minutes

### <Operating Procedures>

The operating procedures in the first step are described making reference to FIG. 6.

Porous-film-containing object to be sealed 11 (Black Diamond™ 3 film, made by the Applied Materials Co.) was loaded into object-to-be-sealed holder 12 within treatment vessel 21. After purging the interior of treatment vessel 21 with an inert gas, the pressure was reduced within treatment vessel 21 by treatment vessel vacuum pump 45. The pressure within treatment vessel 21 was adjusted to 0.03 Torr by pressure regulating mechanism 22. The temperature within treatment vessel 21 was adjusted to −40° C. by temperature regulating mechanism 23. The temperature within treatment vessel 21 was controlled by cooling with liquid nitrogen and heating by an electric heater.

Vacuum housing 24 was installed here to prevent the formation of moisture condensation on the outside of treatment vessel 21 that occurs with the cooling of treatment vessel 21. The pressure in vacuum housing 24 was reduced to 0.01 Torr by vacuum housing vacuum pump 25.

After the pressure and temperature within treatment vessel 21 reached a set value, the first material was supplied to treatment vessel 21 from the first material vessel 31. The supply flow rate was regulated by first material flow regulating mechanism 32. A variable leak valve was used for the first material flow regulating mechanism 32 in this embodiment. Porous film sealing of object to be sealed 11 was carried out by supplying the first material to treatment vessel 21 for 3 minutes.

### <Refractive Index Measurement Method>

Refractometer used: C13027 made by Hamamatsu Photonics

Measurement method: A glass window was installed at the top of treatment vessel 21 and vacuum housing 24. Measurements of the optical porous film refractive index and sealing treatment were carried out at the same time.

### <Experimental Results>

Table 4 below presents the results of evaluation of the refractive index of sealing treated porous films.

In Table 4 above, it can be confirmed that the sealing with the aromatic fluorocarbons of Comparative Example 1 and Comparative Example 2 was insufficient, while in contrast, there was good sealing with non-aromatic fluorocarbon Examples 1 to 14, which were Compound Numbers 1 to 14.

Compound Numbers 1 to 14 were non-aromatic fluorocarbons having 6 or more carbon atoms, and it is thought that because these materials have the properties of a high degree of rotational and extensional freedom in the bonds between atoms in the molecule and low contact angle on porous film, these compounds readily infiltrate and condense in the holes of porous film. Because of this, good sealing conditions were obtained in porous film holes.

### 2.5. The Second Step

After completion of the first step, etching gas was supplied to treatment vessel 21 from etching gas vessel 33. The etching gas flow rate was regulated by etching gas flow regulating system 34 In this embodiment, a mass flow controller was used for etching gas flow regulating mechanism 34. The temperature and pressure within treatment vessel 21 were the same as in the first step. Etching gas was excited by plasma and supplied to treatment vessel 21.

### <Experiment Conditions in the Second Step>

Equipment used: The equipment shown in FIG. 6 was used.

Treatment vessel: Stainless steel vessel, 0.05 L capacity

Temperature: −40° C.

Object to be sealed: Black Diamond™ 3 film purchased from Advantive Technologies

Pressure within treatment vessel: 0.03 Torr

Etching gas: SF₆

Flow rate: 10 SCCM

Etching time: 30 seconds

High frequency power: 60 MHz, 100 W

High frequency bias power 0.4 MHz, 50 W

### <Etching Results>

In Examples 1 to 14, because the porous film holes were in a sufficiently sealed state, the mechanical strength of the porous film improved, and good etching could be achieved without breaking down the porous film holes by plasma etching. On the other hand, in Comparative Examples 1 and 2, because plasma etching was carried out with the porous film holes in an insufficiently sealed state, a partial breakdown of the plasma film was observed.

### 2.6. The Third Step

After the completion of the second step, the supply of etching gas was discontinued. Then, the temperature in treatment vessel 21 was raised by temperature regulating mechanism 23. The pressure within treatment vessel 21 was lowered by pressure regulating mechanism 22. Subsequently, the refractive index of the object to be sealed after the completion of the third step was measured in the same manner as the first step described above. For all of the Examples and Comparative Examples, the refractive index values were the same as the refractive index values of the object to be sealed before sealing treatment. From this fact, it could be confirmed that the porous film sealing material had been removed.

The first step, second step, and third step of this embodiment can be performed with a 601E made by the Alcatel Co. or a Plasma Pro 100 made by Oxford Instruments Co., for example, but the equipment is not limited thereto, and any device known by a person skilled in the art can be used.

### DESCRIPTION OF THE REFERENCE NUMERALS

11 . . . Object to be sealed, 12 . . . Object-to-be-sealed holder, 13 . . . Substrate, 14 . . . Porous film, 15 . . . Hole, 16 . . . First material, 21 . . . Treatment vessel, 22 . . . Pressure regulating mechanism, 23 . . . Temperature control mechanism, 24 . . . Vacuum housing, 25 . . . Vacuum housing pump, 31 . . . First material vessel, 32 . . . First material flow regulating mechanism, 33 . . . Etching gas vessel, 34 . . . Etching gas flow regulating mechanism, 41 . . . Matching box, 42 . . . Electrode, 43 . . . Matching box, 44 . . . Bias supply, 45 . . . Treatment vessel vacuum pump, 46 . . . Exhaust gas, 47 . . . Plasma generation power source, 51 . . . Refrigerant vessel, 61 and 62 . . . Window

It will be understood that many additional changes in the details, materials, steps and arrangement of parts, which have been herein described in order to explain the nature of the invention, may be made by those skilled in the art within the principle and scope of the invention as expressed in the appended claims. Thus, the present invention is not intended to be limited to the specific embodiments in the examples given above.

1. A method to seal a hole within a porous film comprising the step of
supplying a first material to a treatment vessel, the treatment vessel containing an object having the porous film, wherein
the first material comprises a non-aromatic fluorocarbon having 6 or more carbon atoms.

2. The porous film sealing method as claimed in claim 1 wherein,
in the first step,
the first material is introduced into the treatment vessel in a gas state, and wherein
the first material seals the holes within the porous film.

3. The porous film sealing method as claimed in claim 1 wherein,
in the first step,
the first material is introduced into the treatment vessel in a liquid state, and wherein
the first material seals the holes within the porous film.

4. The porous film sealing method as claimed in claim 2 further comprising a second step of forming a plasma from the first material.

5. The porous film sealing method as claimed in claim 4
wherein
the plasma of the first material acts as an etching gas in the second step.

6. The porous film sealing method as claimed in claim 1 further comprising a third step of removing the first material from the holes in the porous film by increasing a temperature within the treatment vessel and/or decreasing a pressure within the treatment vessel.

7. The porous film sealing method as claimed in claim 1, wherein the first material has a ring structure, and a vapor pressure of the first material at a temperature of 25° C. is from 0.05 Torr to 25 Torr.

8. The porous film sealing method as claimed in claim 1, wherein the first material has a straight chain or a branched structure, and a vapor pressure of the first material at a temperature of 25° C. is from 0.05 Torr to 40 Torr.

9. The porous film sealing method as claimed in claim 1, wherein a vapor pressure range of the first material in a temperature range from −50° C. to −20° C. is from 0.0001 Torr to 0.1 Torr.

10. The porous film sealing method as claimed in claim 1, wherein the boiling point of the first material at standard temperature and pressure (STP) is from 100° C. to 400° C.

11. The porous film sealing method as claimed in claim 1, wherein 0% to 20% of a total number of atoms contained within a single molecule of the first material are hydrogen atoms.

12. The porous film sealing method as claimed in claim 1, wherein 0% to 5% of a molecular weight of the first material is comprised of an atomic weight of hydrogen atoms.

13. The porous film sealing method as claimed in claim 1, wherein the first material comprises one or more oxygen atoms and/or one or more nitrogen atoms.

14. The porous film sealing method of claim 1, wherein a contact angle of the first material on the porous film is 5 degrees or less, but greater than 0 degrees.

15. The porous film sealing method of claim 1, wherein the first material is a compound represented by any of the general formulas of general formula (1) to general formula (4) below:
CR¹₃(CR²₂)ₙCR³₃ (1)
(where, in formula (1), the plurality of R¹ are each independently H, F, Cl, CF₃ or CHF₂, the plurality of R² are each independently H, F, Cl, CF₃ or CHF₂, the plurality of R³ are each independently H, F, Cl, CF₃ or CHF₂; and n is an integer from 4 to 15)
CR⁴₃(O(CR⁵₂)ₘ)ₙOCR⁶₃ (2)
(where, in formula (2), the plurality of R⁴ are each independently H, F, Cl, CF₃ or CHF₂, the plurality of R⁵ are each independently H, F, Cl, CF₃ or CHF₂, the plurality of R⁶ are each independently H, F, Cl, CF₃ or CHF₂; n is an integer from 1 to 15, m is an integer from 1 to 4, and the number obtained by multiplying n times m is from 4 to 15) 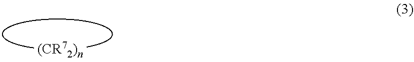
(where, in formula (3), the plurality of R⁷ are each independently H, F, Cl, CF₃ or CHF₂, and n is an integer from 6 to 17) 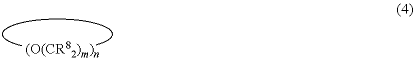
(where, in formula (4), the plurality of R⁸ are each independently H, F, Cl, CF₃ or CHF₂, n is an integer from 2 to 17, m is an integer from 1 to 4, and the number obtained by multiplying n times m is from 6 to 17).

16. The porous film sealing method of claim 1, wherein the first material is at least one compound selected from the group consisting of perfluorotributylamine, perfluorotripentylamine, perfluorotripropylamine, perfluorodecaline, perfluorotetradecahydrophenanthrene, perfluorooctane, perfluorononane, pefluorodecane, perfluoroundecane, perfluorotriglyme, perfluorotetraglyme, perfluoropentaglyme, perfluoro-1,4-dimethylcyclohexane, perfluoro-1,3,5-trimethylcyclohexane, perfluoro-1,2,4,5-tetramethylcyclohexane, perfluoro-15-crown-5-ether, hexafluoropropylene oxide trimer, and combinations thereof.

17. In the porous film sealing method of claim 1, wherein the first material has a purity of 99.9 wt % to 100 wt % and contains 0 wt % to 0.1 wt % water.

18. A porous film sealing material comprising a compound represented by any of the general formulas of general formula (1) to general formula (4) below:
CR¹₃(CR²₂)ₙCR³₃ (1)
(where, in formula (1), the plurality of R¹ are each independently H, F, Cl, CF₃ or CHF₂, the plurality of R² are each independently H, F, Cl, CF₃ or CHF₂, the plurality of R³ are each independently H, F, Cl, CF₃ or CHF₂; and n is an integer from 4 to 15)
CR⁴₃(O(CR⁵₂)ₘ)ₙOCR⁶₃ (2)
(where, in formula (2), the plurality of R⁴ are each independently H, F, Cl, CF₃ or CHF₂, the plurality of R⁵ are each independently H, F, Cl, CF₃ or CHF₂, the plurality of R⁶ are each independently H, F, Cl, CF₃ or CHF₂; n is an integer from 1 to 15, m is an integer from 1 to 4, and the number obtained by multiplying n times m is from 4 to 15) 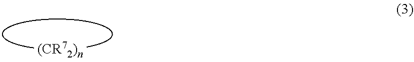
(where, in formula (3), the plurality of R⁷ are each independently H, F, Cl, CF₃ or CHF₂, and n is an integer from 6 to 17) 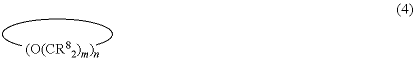
(where, in formula (4), the plurality of R⁸ are each independently H, F, Cl, CF₃ or CHF₂, n is an integer from 2 to 17, m is an integer from 1 to 4, and the number obtained by multiplying n times m is from 6 to 17).

19-28. (canceled)

29. The porous film sealing material of claim 18, wherein the porous film sealing material comprises least one compound selected from the group consisting of perfluorotributylamine, perfluorotripentylamine, perfluorotripropylamine, perfluorodecaline, perfluorotetradecahydrophenanthrene, perfluorooctane, perfluorononane, pefluorodecane, perfluoroundecane, perfluorotriglyme, perfluorotetraglyme, perfluoropentaglyme, perfluoro-1,4-dimethylcyclohexane, perfluoro-1,3,5-trimethylcyclohexane, perfluoro-1,2,4,5-tetramethylcyclohexane, perfluoro-15-crown-5-ether, hexafluoropropylene oxide trimer, and combinations thereof.

30. The porous film sealing material of claim 18, characterized by having a purity of 99.9 wt % to 100 wt % and containing 0 wt % to 0.1 wt % water.
